(19) United States
(12) Patent Application Publication
(10) Pub. No.: US 2015/0311334 A1
(43) Pub. Date: Oct. 29, 2015

(54) SEMICONDUCTOR DEVICE

(71) Applicant: Samsung Electro-Mechanics Co., Ltd., Suwon (KR)

(72) Inventors: Chang Su JANG, Suwon (KR); Ji Hye KIM, Suwon (KR); Kyu Hyun MO, Suwon (KR); Dong Soo SEO, Suwon (KR); Sun Jae YOUN, Suwon (KR)

(73) Assignee: Samsung Electro-Mechanics Co., Ltd., Suwon (KR)

(21) Appl. No.: 14/331,587

(22) Filed: Jul. 15, 2014

(30) Foreign Application Priority Data
Apr. 25, 2014 (KR) 10-2014-0050283

(51) Int. Cl. H01L 29/78; H01L 29/10

(52) U.S. Cl. CPC H01L 29/7804; H01L 29/105; H01L 29/1045

(57) ABSTRACT

A semiconductor device may include a drift layer having a first conductivity-type; a body region having a second conductivity-type and disposed on the drift layer; first semiconductor regions having the second conductivity-type and disposed to be spaced apart from each other below the drift layer; and second semiconductor regions having the first conductivity-type and disposed between the first semiconductor regions below the drift layer.

### CROSS-REFERENCE TO RELATED APPLICATION

This application claims the benefit of Korean Patent Application No. 10-2014-0050283 filed on Apr. 25, 2014, with the Korean Intellectual Property Office, the disclosure of which is incorporated herein by reference.

### BACKGROUND

The present disclosure relates to a semiconductor device.

A diode is a semiconductor device having effects light emitting characteristics, current rectifying characteristics, and the like.

Such a diode includes a p-n junction formed through connections between p-type and n-type semiconductors.

If the p-n junction is formed through connections between the p-type and n-type semiconductors, electrons present in the n-type semiconductor are diffused into the p-type semiconductor having many holes.

The electrons diffused as described above are bonded to the holes in the p-type semiconductor, such that a depletion region in which no carriers are present is formed adjacently to a p-n junction.

When a positive voltage is applied to a p-type semiconductor region and a negative voltage is applied to an n-type semiconductor region, the depletion region is eliminated, such that a current flows through the diode.

Conversely, when a reverse-bias is applied to the semiconductor regions, for example, the negative voltage is applied to the p-type semiconductor region and the positive voltage is applied to the n-type semiconductor region, the depletion region is further increased and the carriers are not present, such that current may not flow freely through the diode.

Recently, a fast switching diode has been required to have fast switching and soft recovery characteristics.

Commonly used p-n junction diodes employ minority carriers, thereby lowering a forward voltage through a conduction modulation effect.

However, since reverse recovery characteristics are caused by the minority carriers, fast switching characteristics may be degraded.

The reverse recovery characteristics refer to a phenomenon in which a high reverse current instantaneously flows when a voltage is applied abruptly in a reverse direction while a forward current is applied to the p-n junction diode, due to a reverse flow of injected minority carriers in the p-n junction, the reverse current referring to a current that flows until the minority carriers are discharged or dissipated.

The fast switching diode has the soft recovery characteristics by reducing a period until the level of the reverse current reaches zero (reverse recovery time: trr) and smoothing a reverse current waveform.

Fast switching diodes are generally classified as fast recovery diodes (FRD), high efficiency diodes (HED), and schottky barrier diodes (SBD).

Thereamong, FRDs have the same structure as general p-n diodes, but are capable of rapidly dissipating the minority carriers after being turned off, by diffusing impurities such as platinum, gold, and the like into silicon, by using electronic lines and irradiation of neutrons, or the like, to thereby increase the amount of recombination centers of electrons and holes.

In order to prompt the rapid dissipation of the minority carriers, in the case in which the impurities, such as platinum, gold, and the like, are diffused into the silicon by using electronic lines and irradiation of neutrons, forward voltage (VF) characteristics are degraded.

Accordingly, a diode having excellent VF characteristics while improving diode recovery characteristics is in demand.

The following Related Art Document (Patent Document 1) discloses a diode.

### RELATED ART DOCUMENT

(Patent Document 1) Japanese Patent Laid-Open Publication No. 2009-043924

### SUMMARY

An exemplary embodiment in the present disclosure may provide a semiconductor device having excellent recovery characteristics and excellent forward voltage (VF) characteristics.

According to an exemplary embodiment in the present disclosure, a semiconductor device may include: a drift layer having a first conductivity-type; a body region having a second conductivity-type and disposed on the drift layer; first semiconductor regions having the second conductivity-type and disposed to be spaced apart from each other below the drift layer; and second semiconductor regions having the first conductivity-type and disposed between the first semiconductor regions below the drift layer.

A total impurity concentration in a lower portion of the drift layer may be higher than that in a central portion of the drift layer.

The second semiconductor region may provide a path allowing electrons to move.

The second semiconductor region may be thicker than the first semiconductor region.

A width of the second semiconductor region may be greater than that of the first semiconductor region.

The second semiconductor region may have an impurity concentration higher than that of the first semiconductor region.

The second semiconductor region may be spaced apart from the first semiconductor region.

According to an exemplary embodiment in the present disclosure, a semiconductor device may include: a drift layer having a first conductivity-type; a body region having a second conductivity-type and disposed on the drift layer; first semiconductor regions having the second conductivity-type and second semiconductor regions having the first conductivity-type, the first and second semiconductor regions being alternately disposed below the drift layer.

A peak point of a profile of a total impurity concentration from a central portion of the drift layer to a lower portion thereof in a depth direction may be formed at a position at which the first and second semiconductor regions alternate with each other.

The second semiconductor region may provide a path allowing electrons to move.

The second semiconductor region may be thicker than the first semiconductor region.

A width of the second semiconductor region may be greater than that of the first semiconductor region.

The second semiconductor region may have an impurity concentration higher than that of the first semiconductor region.

### BRIEF DESCRIPTION OF THE DRAWINGS

The above and other aspects, features and advantages of the present disclosure will be more clearly understood from the following detailed description taken in conjunction with the accompanying drawings, in which:

FIG. 1 is a schematic cross-sectional view of a semiconductor device according to an exemplary embodiment of the present disclosure;

FIG. 2 is a graph illustrating a total amount of impurities according to a depth, in a semiconductor device according to an exemplary embodiment of the present disclosure;

FIG. 3 is a graph illustrating current variations measured during a switching operation of a semiconductor device according to an exemplary embodiment of the present disclosure;

FIG. 4 is an enlarged view of portion B of FIG. 3;

FIG. 5 is a schematic cross-sectional view of a semiconductor device according to another exemplary embodiment of the present disclosure; and

FIG. 6 is a schematic cross-sectional view of a semiconductor device according to another exemplary embodiment of the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements maybe exaggerated for clarity, and the same reference numerals will be used throughout to designate the same or like elements.

In the drawings, an X direction refers to a width direction of a semiconductor device and a Y direction refers to a depth direction thereof.

A power switch may be formed of any one of a power metal oxide semiconductor field effect transistor (MOSFET), an insulated gate bipolar transistor (IGBT), a thyristor, and devices similar to those listed above. Most of novel technologies disclosed herein will be described based on diodes. However, several exemplary embodiments of the present disclosure are not limited to diodes, but may also be applied to different types of power switch technology, including power MOSFETs and several types of thyristors, in addition to diodes, for example. Further, several exemplary embodiments of the present disclosure will be described as including specific p-type and n-type regions. However, conductivity-types of several regions disclosed herein may be similarly applied to devices having conductivity-types opposite thereto.

In addition, n-type and p-type, as used hereinafter, may be respectively defined as a first conductivity type and a second conductivity type. Meanwhile, the first and second conductivity-types are different conductivity-types.

Further, ‘+’ generally refers to a state in which a region is heavily doped, while ‘−’ generally refers to a state in which a region is lightly doped.

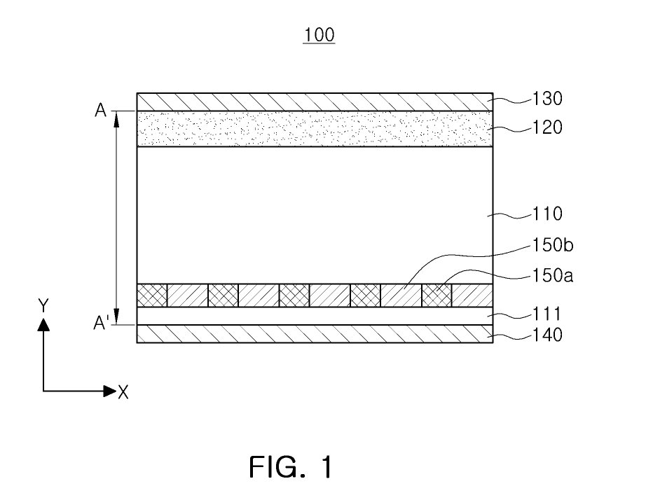

FIG. 1 is a schematic cross-sectional view of a semiconductor device 100 according to an exemplary embodiment of the present disclosure.

The semiconductor device 100 according to the exemplary embodiment of the present disclosure may include an n-type drift layer 110 and a p-type body region 120.

Specifically, the semiconductor device 100 according to the exemplary embodiment of the present disclosure may include an n-type drift layer 110; the p-type body region 120 formed in an upper portion of the drift layer 110; a plurality of first semiconductor regions 150a having a p-type conductivity, formed in a lower portion of the drift layer 110, and spaced apart from each other; and a plurality of second semiconductor regions 150b having an n-type conductivity, formed in the lower portion of the drift layer 110, and formed between the first semiconductor regions 150a.

The drift layer 110 may be an n-type semiconductor region having a low impurity concentration.

The body region 120 may be formed by implanting p-type impurities into the upper portion of the drift region 110.

A plurality of body regions 120 may be formed in at least portions of the upper portion of the drift layer 110.

In the case in which the drift layer 110 and the body region 120 are in contact with each other, electrons and holes respectively present in the drift layer 110 and the body region 120 are combined with each other.

As a result, a depletion region may be formed in a contact region between the drift layer 110 and the body region 120.

In the case in which backward bias is applied to the semiconductor device, the depletion region may be further expanded, and since the depletion region has no carriers present therein, no current flows through the semiconductor device.

That is, an extremely small amount of current passes through the diode in the backward bias section.

However, if a voltage exceeding a backward limitation voltage or a withstand voltage is supplied to the diode, the diode may cause an avalanche breakdown, and thus, a large amount of current may flow in the backward direction.

Therefore, in order to increase the withstand voltage, the drift layer 110 needs to have a thickness sufficient to allow the depletion region to be expanded.

The semiconductor device 100 according to the exemplary embodiment of the present disclosure may further include an n-type buffer region 111 having a high concentration below the drift layer 110.

The buffer region 111 may have an impurity concentration higher than that of the drift layer 110.

The buffer region 111 may have an impurity concentration higher than that of the drift layer 110, thereby preventing the depletion region from being expanded.

Therefore, in the case in which the buffer region 111 is formed, the thickness of the drift layer 110 may be decreased.

An anode metal layer 130 may be formed on the body region 120, and a cathode metal layer 140 may be formed below the drift region 110 or the buffer region 111.

As described above, in the case of the semiconductor device 100 according to the exemplary embodiment of the present disclosure, while the forward bias is applied thereto and current flows therethrough, a switching operation may be performed such that the backward bias is applied to the semiconductor device, the current does not flow through the semiconductor device any longer.

However, in the instant of applying the backward bias, since the holes, minority carriers, are not rapidly dissipated, the residual carriers remain in the semiconductor device, thereby degrading switching characteristics.

In the semiconductor device 100 according to the exemplary embodiment of the present disclosure, the first semiconductor region 150a having a p-type conductivity may be formed in the lower portion of the drift layer 110, thereby improving switching characteristics.

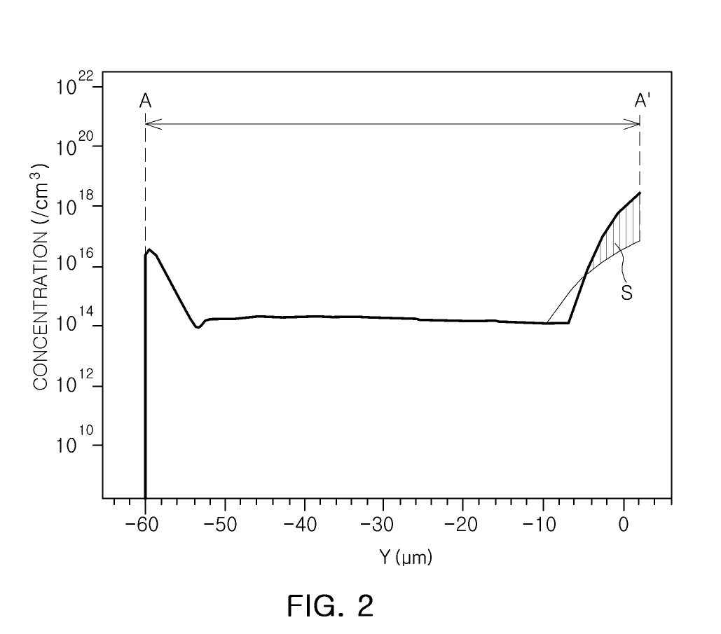

FIG. 2 is a graph illustrating a total amount of impurities according to depth, in a semiconductor device according to an exemplary embodiment of the present disclosure.

A solid line in FIG. 2 illustrates a total amount of impurities in a semiconductor device according to the related art (comparative example) and a bold line illustrates a total amount of impurities in a semiconductor device according to an exemplary embodiment of the present disclosure (inventive example).

Referring to FIG. 2, it may be appreciated that the total amount of impurities in most of the drift layer 110 is identical in both the comparative example and the inventive example, but the total amount of impurities in the lower portion of the drift layer 110 is different.

As illustrated in FIG. 2, it may be appreciated that the total amount of impurities in the lower portion of the drift layer 110 is larger in the inventive example than in the comparative example.

That is, in a profile of the total impurity concentration from a central portion of the drift layer 110 to the lower portion thereof in the depth direction (the Y direction), it may be appreciated that the lower portion of the drift layer 110 has an impurity concentration higher than that of the central portion of the drift layer 110.

Particularly, a peak point of the profile of the total impurity concentration from the central portion of the drift layer 110 to the lower portion thereof may be located in the second semiconductor region.

As such, in the case in which the first semiconductor region 150a is formed by implanting p-type impurities into the lower portion of the drift layer 110, the total amount of impurities may be increased as in a region S of FIG. 2 and the semiconductor device may have soft recovery characteristics.

In the case in which the total amount of impurities is increased as in the region S of FIG. 2, mobility of the holes, the minority carriers, may be increased, and thus, the holes may be rapidly dissipated, as compared to the related art.

Particularly, since the holes are quickly dissipated in the drift layer, the number of minority carriers affecting the current at a point at which the backward bias is applied maybe decreased, whereby the semiconductor device may have the soft recovery characteristics.

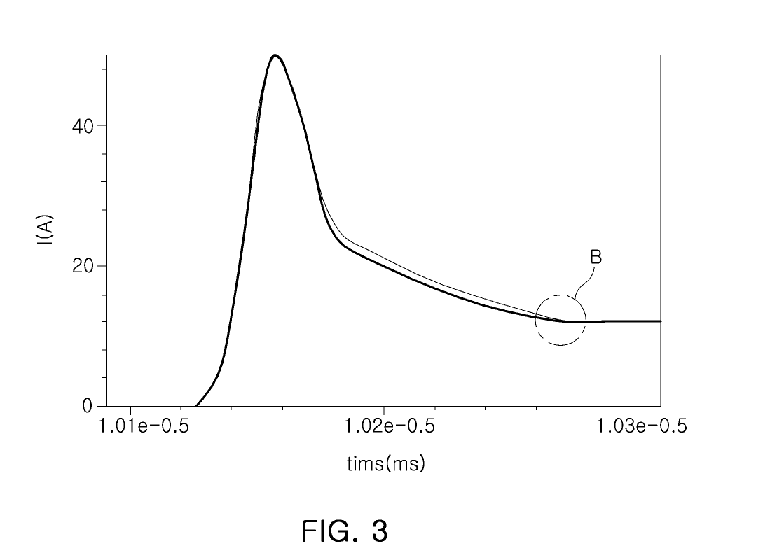

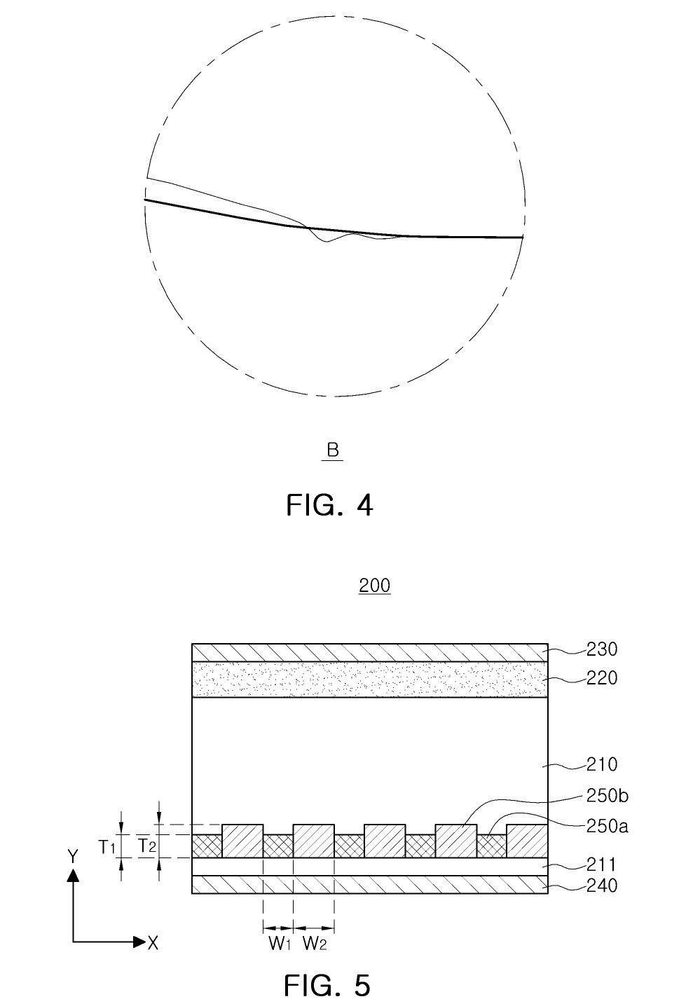

An effect obtained by improving the soft recovery characteristics will be described with reference to FIGS. 3 and 4.

FIG. 3 is a graph (bold line: inventive example and thin line: comparative example) illustrating current variations measured during a switching operation of a semiconductor device according to an exemplary embodiment of the present disclosure, and FIG. 4 is an enlarged view of portion B of FIG. 3.

Referring to FIG. 3, it may be appreciated that a current in the semiconductor device according to the inventive example is more quickly converged as compared to the comparative example.

That is, as illustrated in FIG. 3, after the peak point, the bold line is located below the thin line and the current is more quickly converged to a predetermined value.

Accordingly, it may be appreciated that the semiconductor device according to the inventive example has excellent fast switching performance.

That is, since the holes, the minority carriers, may be quickly dissipated at the time of a turn-off operation, the semiconductor device according to the inventive example may have an increased switching speed.

Further, as illustrated in FIG. 4, it may be appreciated that current in the semiconductor device according to the comparative example is decreased while forming a wave, but current in the semiconductor device according to the inventive example is smoothly converged to the predetermined value due to the first semiconductor regions 150a.

Accordingly, the diode according to the exemplary embodiment of the present disclosure may have excellent soft recovery characteristics.

As described in the background, in the case in which the switching performance is improved, the VF characteristics are generally degraded.

Also, in the case in which only the first semiconductor regions 150a are formed in the semiconductor device 100 according to the exemplary embodiment of the present disclosure, the switching speed and the soft recovery characteristics of the semiconductor device 100 may be improved, such that the switching characteristics are improved. However, since a region allowing current to flow is decreased due to the first semiconductor regions 150a, the VF characteristics may be degraded.

In order to solve the above-described problems, the semiconductor device according to the exemplary embodiment of the present disclosure may have the second semiconductor regions 150b having an n-type conductivity and formed between the first semiconductor regions 150a.

That is, the first semiconductor regions 150a and the second semiconductor regions 150b may be alternately formed in the width direction (the X direction).

Since the second semiconductor regions 150b have an n-type conductivity, they may have relatively low resistance against the electronic current.

The second semiconductor regions 150b may have an impurity concentration higher than that of the drift layer 110.

The second semiconductor regions 150a may be located between the first semiconductor regions 150a to provide a path through which the current may easily flow.

Accordingly, in the case in which the second semiconductor regions 150b are formed, the VF characteristics of the semiconductor device 100 may be improved.

FIG. 5 is a schematic cross-sectional view of a semiconductor device 200 according to another exemplary embodiment of the present disclosure.

A description of elements the same as those illustrated in FIG. 1, among the elements illustrated in FIG. 5, will be omitted.

Referring to FIG. 5, a thickness T2 of a second semiconductor region 250b may be larger than a thickness T1 of a first semiconductor region 250a.

Since the thickness T2 of the second semiconductor region 250b is larger than the thickness T1 of the first semiconductor region 250a, a potential barrier experienced by the electronic current is decreased, such that the electronic current may flow more easily.

Accordingly, in the case in which T2>T1 is satisfied, the VF characteristics of the semiconductor device 200 may be further improved.

In order to form T2 to be larger than T1, more impurities may be implanted into the second semiconductor regions 250b to have a higher impurity concentration as compared to the impurity concentration of the first semiconductor regions 250a and be heated to be diffused, but the present inventive concept is not limited thereto.

Accordingly, a width W1 of the first semiconductor region 250a may be less than a width W2 of the second semiconductor region 250b.

Since W2>W1 is satisfied, in the case in which the first semiconductor region 250a and the second semiconductor region 250b have the same or similar impurity concentration as each other, all of the second semiconductor regions 250b may not be depleted.

Accordingly, the VF characteristics of the semiconductor device 200 according to the exemplary embodiment of the present disclosure may be improved.

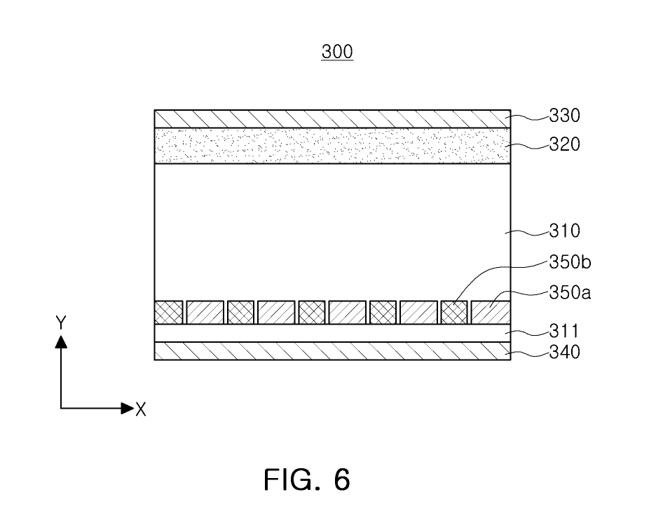

FIG. 6 is a schematic cross-sectional view of a semiconductor device 300 according to another exemplary embodiment of the present disclosure.

A description of elements the same as those illustrated in FIG. 1, among the elements illustrated in FIG. 6, will be omitted.

Referring to FIG. 6, first semiconductor regions 350 and second semiconductor regions 350b may be formed to be spaced apart from each other.

The aforementioned exemplary embodiments may be not only adopted independently, but also be combined with each other according to intended purpose.

For example, excellent switching characteristics and excellent VF characteristics may be simultaneously achieved by adjusting the impurity concentrations of the first and second semiconductor regions and adjusting the widths thereof, the thicknesses thereof, and the like.

As set forth above, according to exemplary embodiments of the present disclosure, the semiconductor device has the first p-type semiconductor regions such that it can achieve the soft recovery characteristics when the backward bias is applied to the semiconductor device, whereby the switching characteristics may be improved.

In addition, the semiconductor device has the second n-type semiconductor regions providing a path through which the electrons pass, whereby the VF characteristics may be improved.

While exemplary embodiments have been shown and described above, it will be apparent to those skilled in the art that modifications and variations could be made without departing from the spirit and scope of the present disclosure as defined by the appended claims.

What is claimed is:

1. A semiconductor device, comprising:
a drift layer having a first conductivity-type;
a body region having a second conductivity-type and disposed on the drift layer;
first semiconductor regions having the second conductivity-type and disposed to be spaced apart from each other below the drift layer; and
second semiconductor regions having the first conductivity-type and disposed between the first semiconductor regions below the drift layer.

2. The semiconductor device of claim 1, wherein a total impurity concentration in a lower portion of the drift layer is higher than that in a central portion of the drift layer.

3. The semiconductor device of claim 1, wherein the second semiconductor region provides a path allowing electrons to move.

4. The semiconductor device of claim 1, wherein the second semiconductor region is thicker than the first semiconductor region.

5. The semiconductor device of claim 1, wherein a width of the second semiconductor region is greater than that of the first semiconductor region.

6. The semiconductor device of claim 1, wherein the second semiconductor region has an impurity concentration higher than that of the first semiconductor region.

7. The semiconductor device of claim 1, wherein the second semiconductor region is spaced apart from the first semiconductor region.

8. A semiconductor device, comprising:
a drift layer having a first conductivity-type;
a body region having a second conductivity-type and disposed on the drift layer;
first semiconductor regions having the second conductivity-type and second semiconductor regions having the first conductivity-type, the first and second semiconductor regions being alternately disposed below the drift layer.

9. The semiconductor device of claim 8, wherein a peak point of a profile of a total impurity concentration from a central portion of the drift layer to a lower portion thereof in a depth direction is formed at a position at which the first and second semiconductor regions alternate with each other.

10. The semiconductor device of claim 8, wherein the second semiconductor region provides a path allowing electrons to move.

11. The semiconductor device of claim 8, wherein the second semiconductor region is thicker than the first semiconductor region.

12. The semiconductor device of claim 8, wherein a width of the second semiconductor region is greater than that of the first semiconductor region.

13. The semiconductor device of claim 8, wherein the second semiconductor region has an impurity concentration higher than that of the first semiconductor region.
